(19) United States
(12) Patent Application Publication
(10) Pub. No.: US 2008/0203395 A1
(43) Pub. Date: Aug. 28, 2008

(54) SEMICONDUCTOR DEVICE AND MANUFACTURING METHOD THEREOF

(75) Inventors: Chih-Wei Chao, Hsinchu (TW); Chien-Sen Weng, Hsinchu (TW); MING-WEI SUN, Hsinchu (TW); Yi-Wei Chen, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: AU OPTRONICS CORPORATION, Hsinchu (TW)

(21) Appl. No.: 11/743,676

(22) Filed: May 3, 2007

(30) Foreign Application Priority Data
Feb. 26, 2007 (TW) 96106382

(51) Int. Cl. H01L 29/04; H01L 21/336; H01L 29/786

(52) U.S. Cl. 257/72; 438/166; 257/E29.003; 257/E29.273; 257/E21.409

(57) ABSTRACT

A semiconductor device and a method for manufacturing the same are provided. First, a transparent substrate is provided. Next, a light-shielding layer is formed over the transparent substrate and a first buffer layer is formed to cover the light-shielding layer. A semiconductor layer is formed over the first buffer layer. Then, the light-shielding layer, the first buffer layer and the semiconductor layer are patterned to form a laminate pattern. A channel and a source/drain region at two sides of the channel are formed within the semiconductor layer. Then, a gate insulating layer is formed over the transparent substrate to cover the laminate pattern. A gate electrode is formed on the gate insulating layer above the channel.

### CROSS-REFERENCE TO RELATED APPLICATION

This application claims the priority benefit of Taiwan application serial no. 96106382, filed Feb. 26, 2007. All disclosure of the Taiwan application is incorporated herein by reference.

### BACKGROUND OF THE INVENTION

1. Field of the Invention

The present invention relates to a method for manufacturing a semiconductor device, and more particularly, to a method for manufacturing a semiconductor device that is adapted to reduce external light interference.

2. Description of Related Art

As modern information technology advances, various types of displays have been widely used in screens for consumer electronic products such as mobile phones, notebook computers, digital cameras, and personal digital assistants (PDAs). Among these displays, liquid crystal displays (LCD) and organic electroluminescence displays (OELD) are the prevailing products in the market due to their advantages of being light-weight, compact, and low in power-consumption. The manufacturing process for both LCD and OELD includes forming semiconductor devices arranged in array on a substrate and the semiconductor devices include thin film transistors (TFTs).

Generally, conventional thin film transistors are either top-gate TFTs or bottom-gate TFTs. Top-gate TFTs generate photocurrent after being shone with light from a front-light, a backlight or an external light. FIG. 1 schematically illustrates the optical current leakage effect of a backlight on a top-gate TFT. As shown in FIG. 1, curve C_{A} is the current voltage curve obtained when the backlight is turned off and no light is shone on the top-gate TFT, and curve C_{B} is the current voltage curve obtained when the backlight is turned on and light is directly shone on the top-gate TFT. Based on FIG. 1, when the backlight is turned on, the amount of current generated by the TFT is significantly larger than that when the backlight is turned off. Such increase of current in the semiconductor device due to unnecessary, external lights explains the occurrence of optical current leakage.

FIG. 2A schematically illustrates a conventional thin film transistor. In FIG. 2A, a thin film transistor 100 includes a substrate 110, a silicon nitride layer 120, a silicon oxide layer 130, an active layer 140, a gate insulating layer 150, and a gate 160. Herein, the active layer 140 includes a source region 142, a drain region 144, and a channel 146. FIG. 2B illustrates the light transmittance through the active layer in the thin film transistor when light is shone on the thin film transistor from the backlight. As shown in FIG. 2, when the backlight is turned on, lights L1 with different wavelengths are shone through the substrate 110 and about 90% of the light actually reaches the active layer 140. The light that reaches the active layer 140 generates some photoelectrons in the channel 146. These photoelectrons interfere with the current generated by the device when under normal operation. As a result, the amount of current generated by the thin film transistor is larger when light is shone compared to that when light is not shone. In view of the above, when light from the backlight is shone on the active layer 140 of the thin film transistor 100, photoelectric effect is induced. Consequently, the amount of current in the channel 146 of the thin film transistor 100 increases abnormally, resulting in what is known as optical current leakage. The occurrence of optical current leakage does not only affect the efficiency of the thin film transistor 100, such phenomenon very likely causes problems such as flicker and cross-talk when displaying images.

FIG. 3A schematically illustrates another semiconductor device used in a photo-sensor which is a positive-intrinsic-negative (PIN) diode (i.e. a diode consisting of a p-doped region and an n-doped region separated by an intrinsic region). In FIG. 2A, a semiconductor device 200 includes a substrate 210, an active layer 220, a protection layer 230, a first contact 240, and a second contact 250. Herein, the active layer includes a first-type doped region 222, an intrinsic region 226 and a second-type doped region 224. When an external light L2 is shone to the intrinsic region 226, electrons and holes are produced to form photocurrent. Next, the photocurrent is outputted through the first contact 240 and the second contact 250. The semiconductor device 200 can be used as a detector for detecting the amount of the external light L2 for a liquid crystal display in order to adjust the brightness of the backlight module. However, in this application, unnecessary lights from the backlight interfere with the excitation of the electrons and holes in the intrinsic region 226. Consequently, errors are resulted when the semiconductor device determines the amount of the external light L2, causing inaccuracy when adjusting the brightness of the backlight module and resulting in abnormal display.

In addition, the semiconductor device 200 can be used in a touch panel to act as a switch by detecting the presence and absence of an external light. FIG. 3B schematically illustrates the influence of an external light on the output current of a semiconductor device used in a touch panel. In FIG. 3B, the curve obtained based on the light current LI that is generated when being blocked by an object and the curve obtained based on the dark current DI that is generated when being blocked by no object are similar. According to the curves, the semiconductor device 200 does not show significantly different detection towards LI and DI, thus lowering the sensitivity of the semiconductor device 200. This is because the light of the backlight in the side of the substrate incessantly interferes with the semiconductor device 200 regardless whether an object is blocking the external light L2.

Accordingly, regardless of the application of a semiconductor device, the interference caused by unnecessary lights to the semiconductor device must be reduced in order to fully utilize the semiconductor device.

### SUMMARY OF THE INVENTION

The present invention is directed to a method for manufacturing a semiconductor device that is adapted to reduce the interference of unnecessary lights on the semiconductor device in order to improve the photoelectric properties of the semiconductor device.

The present invention is also directed to a semiconductor device that is adapted to prevent the interference of an unnecessary light source, thus having superior photoelectric properties.

To specifically describe the present invention, a method for fabricating a semiconductor device is provided. First, a transparent substrate is provided. Next, a light-shielding layer is formed over the transparent substrate. After a first buffer layer is formed on the light-shielding layer, a semiconductor layer is formed over the first buffer layer. In one embodiment of the present invention, the method used for fabricating the semiconductor layer includes forming an amorphous silicon layer on the first buffer layer, followed by performing a laser annealing process to the amorphous silicon layer to transform the amorphous silicon layer into a polysilicon layer. Herein, the aforementioned laser annealing process is, for example, an excimer laser annealing (ELA) process, a sequential lateral solidification (SLS) process, or a thin beam direction X'rystallization process. After the semiconductor layer is formed, the light-shielding layer, the first buffer layer and the semiconductor layer are patterned to form a laminate pattern. The method used for patterning the light-shielding layer, the first buffer layer and the semiconductor layer is, for example, performing a wet etching process. Next, a channel and a source/drain region at two sides of the channel are formed within the semiconductor layer. In an embodiment, the method used for forming the source/drain region is, for example, performing an ion implantation process to a portion of the semiconductor layer. Thereafter, a gate insulating layer is formed over the transparent substrate to cover the laminate pattern. Finally, a gate electrode is formed on the gate insulating layer above the channel.

In one embodiment of the present invention, the method for fabricating a semiconductor device further includes forming a second buffer layer on a transparent substrate prior to the formation of a light-shielding layer.

In one embodiment of the present invention, the used method for fabricating a semiconductor device further includes forming a third buffer layer on the light-shielding layer prior to the formation of the first buffer layer.

The present invention is also directed to a semiconductor device, including a transparent substrate, a light-shielding layer, a first buffer layer, a semiconductor layer, a gate insulating layer and a gate electrode. Herein, the light-shielding layer is disposed on the transparent substrate and the material used for fabricating the light-shielding layer includes amorphous silicon, polysilicon, diamond-like carbon, silicon germanium (SiGe), germanium, gallium arsenide (GaAs) or a combination thereof. The light-shielding layer is at least 10 nm thick. In an embodiment, the thickness of the light-shielding layer is between 50 nm and 300 nm. Further, the first buffer layer is disposed on the light-shielding layer and the material used for fabricating the first buffer layer is, for example, silicon oxide. Moreover, the semiconductor layer is disposed on the first buffer layer and the semiconductor layer includes a channel and a source/drain region on two sides of the channel. A laminate pattern is formed by the light-shielding layer, the first buffer layer and the semiconductor layer that have substantially the same pattern. The shape of the laminate pattern is, for example, an island. Furthermore, a gate insulating layer is disposed on the transparent substrate to cover the laminate pattern. A gate electrode is disposed on the gate insulating layer above the channel.

In one embodiment of the present invention, a semiconductor device further includes a second buffer layer disposed between the light-shielding layer and the transparent substrate. The material used for fabricating the second buffer layer is, for example, silicon nitride.

In one embodiment of the present invention, a semiconductor device further includes a third buffer layer disposed between the first buffer layer and the light-shielding layer. The material used for fabricating the third buffer layer is, for example, silicon nitride. In this type of structure, the material used for fabricating the light-shielding layer does not only include amorphous silicon, polysilicon, diamond-like carbon, silicon germanium (SiGe) alloy/compound, germanium, gallium arsenide (GaAs) or a combination thereof, it also includes molybdenum (Mo), aluminum (Al), chromium (Cr), titanium (Ti), or an alloy thereof.

The present invention is also directed to a method for fabricating a semiconductor, which includes the following steps. First, a transparent substrate is provided. Next, a light-shielding layer is formed over the transparent substrate. After a first buffer layer is formed on the light-shielding layer, a semiconductor layer is formed over the first buffer layer. In one embodiment of the present invention, the method used for fabricating the semiconductor layer includes forming an amorphous silicon layer on the first buffer layer, and followed by performing a laser annealing process to the amorphous silicon layer to transform the amorphous silicon layer into a polysilicon layer. The aforementioned laser annealing process is, for example, an excimer laser annealing (ELA) process, a sequential lateral solidification (SLS) process, or a thin beam direction X'rystallization process. After the semiconductor layer is formed, the light-shielding layer, the first buffer layer and the semiconductor layer are patterned to form a laminate pattern. The method used for patterning the light-shielding layer, the first buffer layer and the semiconductor layer includes, for example, performing a wet etching process. Afterward, an intrinsic region, and a first-type doped region and a second-type doped region at two sides of the intrinsic region are formed within the semiconductor layer. The method used for fabricating the first-type doped region and the second-type doped region respectively includes performing a P-type doping and an N-type doping to different portions of the semiconductor layer. Thereafter, a protection layer is formed on the transparent substrate to cover the laminate pattern. Herein the protection layer includes a first contact window and a second contact window, which are respectively used to expose a portion of the first-type doped region and that of the second-type doped region. Finally, a first contact and a second contact are formed on the protection layer. Herein, the first contact is electrically connected to the first-type doped region through the first contact window and the second contact is electrically connected to the second-type doped region through the second contact window.

In one embodiment of the present invention, the method used for fabricating a semiconductor device further includes forming a second buffer layer on the transparent substrate prior to the formation of the light-shielding layer.

In one embodiment of the present invention, the method for fabricating a semiconductor device further includes forming a third buffer layer on the light-shielding layer prior to the formation of the first buffer layer.

The present invention is also directed to a semiconductor device that includes a transparent substrate, a light-shielding layer, a first buffer layer, a semiconductor layer, a protection layer, a first contact and a second contact. Herein, the light-shielding layer is disposed on the transparent substrate and the material used for fabricating the light-shielding layer includes amorphous silicon, polysilicon, diamond-like carbon, silicon germanium (SiGe), germanium, gallium arsenide (GaAs) or a combination thereof. Additionally, in one embodiment of the present invention, a light-shielding layer is at least 10 nm thick. More preferably, the thickness of the light-shielding layer is between 50 nm and 300 nm. Further, the first buffer layer is disposed on the light-shielding layer and the material used for fabricating the first buffer layer is, for example, silicon oxide. A semiconductor layer is disposed on the first buffer layer and the semiconductor layer includes an intrinsic region, a first-type doped region, and a second-type doped region at two sides of the intrinsic region. A laminate pattern is formed by the light-shielding layer, the first buffer layer and the semiconductor layer that have substantially the same pattern. The shape of the laminate pattern is, for example, an island. Further, a protection layer is formed on the transparent substrate to cover the laminate pattern. Herein, the protection layer includes a first contact window and a second contact window, which are respectively used to expose a portion of the first-type doped region and that of the second-type doped region. The first contact and the second contact are disposed on the protection layer. Herein, the first contact is electrically connected to the first-type doped region through the first contact window and the second contact is electrically connected to the second-type doped region through the second contact window.

In one embodiment of the present invention, a semiconductor device further includes a second buffer layer disposed between a light-shielding layer and a transparent substrate, and the material used for fabricating the second buffer layer is, for example, silicon nitride.

In one embodiment of the present invention, a semiconductor device further includes a third buffer layer disposed between a first buffer layer and a light-shielding layer, and the material used for fabricating the third buffer layer is, for example, silicon nitride. In this type of structure, the material used for fabricating the light-shielding layer does not only include amorphous silicon, polysilicon, diamond-like carbon, silicon germanium (SiGe) alloy/compound, germanium, gallium arsenide (GaAs) or a combination thereof, it can also be molybdenum (Mo), aluminum (Al), chromium (Cr), titanium (Ti), or an alloy thereof.

The semiconductor device of the present invention uses the light-shielding layer to block unnecessary lights in order to effectively reduce interferences caused by unnecessary external lights or an unnecessary backlight to the semiconductor device. Further, the fabrication of the light-shielding layer is compatible to the fabrication of the semiconductor device. The fabrication process is easy and does not require additional photo-mask fabrication. In addition, the production yield is improved and the manufacturing cost is reduced.

In order to make the aforementioned and other objects, features and advantages of the present invention more comprehensible, embodiments accompanied with figures are described in detail below.

### BRIEF DESCRIPTION OF THE DRAWINGS

FIG. 1 schematically illustrates the optical current leakage effect of a backlight on a top-gate TFT.

FIG. 2A schematically illustrates a conventional thin film transistor.

FIG. 2B illustrates the light transmittance of the active layer in the conventional thin film transistor when light is shone on the thin film transistor from the backlight B.

FIG. 3A schematically illustrates another semiconductor device used in a photo-sensor.

FIG. 3B schematically illustrates the influence of an external light on the output current of a conventional semiconductor device used in a touch panel.

FIG. 4 schematically illustrates a thin film transistor used in a liquid crystal display according to one embodiment of the present invention.

FIG. 5A through FIG. 5D schematically illustrate the steps for fabricating a thin film transistor according to one embodiment of the present invention.

FIG. 6 schematically illustrates a thin film transistor according to another embodiment of the present invention.

FIG. 7 illustrates the light transmittance of the light shone from the backlight B through the thin film transistor of FIG. 6 that reaches the semiconductor layer.

FIG. 8 schematically illustrates a thin film transistor according to another embodiment of the present invention.

FIG. 9 schematically illustrates a PIN diode used in a photo-sensor according to one embodiment of the present invention.

FIG. 10A through FIG. 10F schematically illustrate the steps for fabricating a PIN diode according to an embodiment of the present invention.

FIG. 11 schematically illustrates the influence of an external light on the output current of a semiconductor device used in a touch panel.

FIG. 12 schematically illustrates another PIN diode used in a touch panel.

FIG. 13 schematically illustrates another PIN diode used in a touch panel.

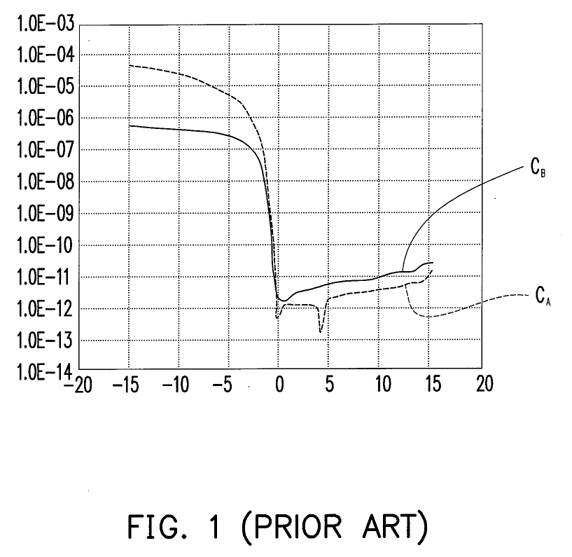

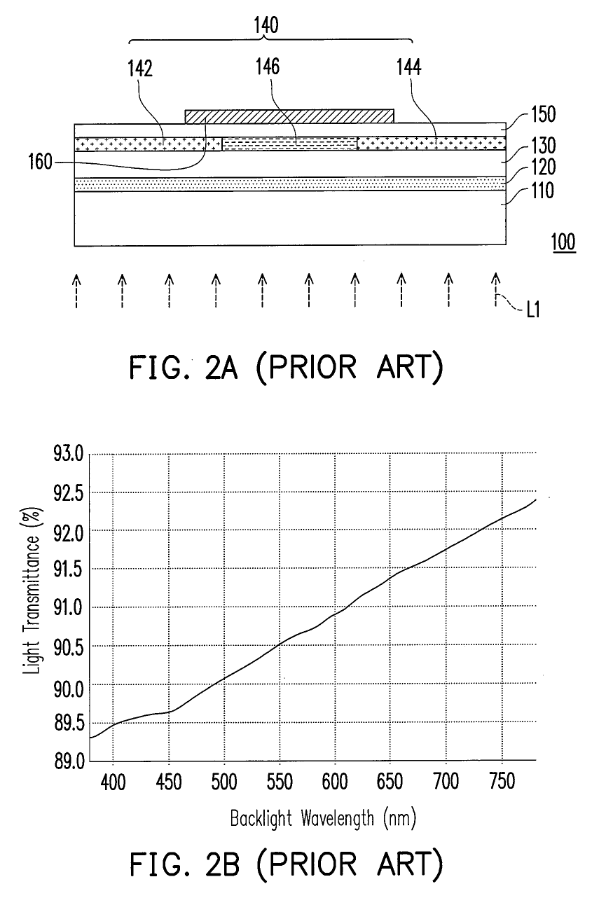

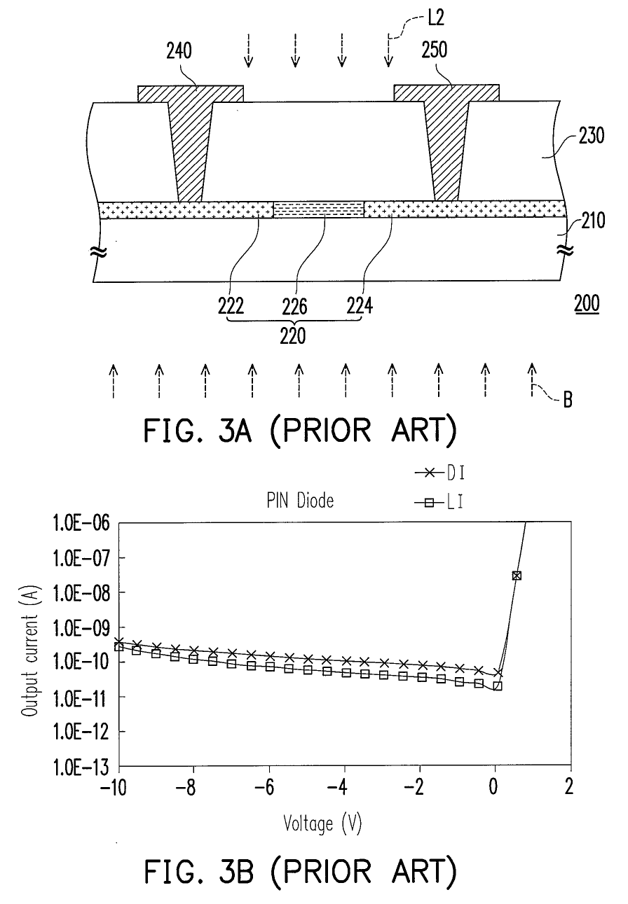

### DESCRIPTION OF EMBODIMENTS

The present invention reduces the interferences caused by unnecessary lights to the operation of a semiconductor device by additionally forming a light-shielding layer in the semiconductor device. In view of the above, the present invention can be broadly applied in all types of semiconductor devices where special requirements for the effects of external lights are desired. For example, a thin film transistor that functions as a driving device in a liquid crystal display or a PIN diode that is used as a photo-sensor can utilize the present invention to improve the photoelectric properties and the efficiency of the device. The above-mentioned thin film transistor and PIN diode are used as examples to illustrate the embodiments of the present invention below. Further, anyone skilled in the related art can apply the technique of the present invention to similar fields to achieve similar effects.

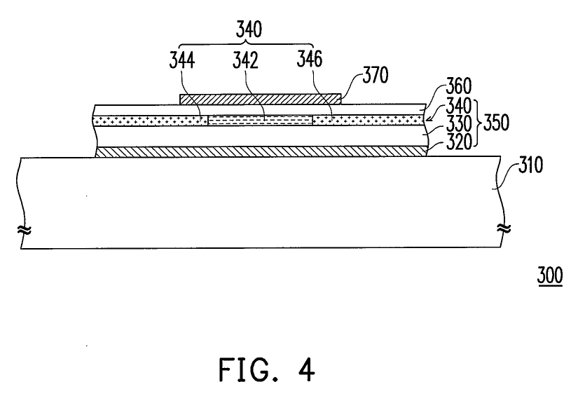

FIG. 4 schematically illustrates a semiconductor device used in a liquid crystal display according to one embodiment of the present invention. This type of semiconductor is, for example, a thin film transistor. In FIG. 4, a thin film transistor 300 includes a transparent substrate 310, a light-shielding layer 320, a first buffer layer 330, a semiconductor layer 340, a gate insulating layer 360, and a gate electrode 370. Herein, the light-shielding layer 320 is disposed on the transparent substrate 310 and the material used for fabricating the light-shielding layer 320 includes amorphous silicon, polysilicon, diamond-like carbon, silicon germanium (SiGe), germanium, gallium arsenide (GaAs) or a combination thereof. The light-shielding layer 320 is at least 10 nm thick. Preferably, the thickness of the light-shielding layer 320 is between 50 nm and 300 nm. Further, the first buffer layer 330 is disposed on the light-shielding layer 320 and the material used for fabricating the first buffer layer 330 is, for example, silicon oxide. Moreover, the semiconductor layer 340 is disposed on the first buffer layer 330 and the semiconductor layer 340 includes a channel 342 and a source region 344/drain region 346 on two sides of the channel 342. A laminate pattern 350 is formed by the light-shielding layer 320, the first buffer layer 330 and the semiconductor layer 340 that have substantially the same pattern. The light-shielding layer 320, the first buffer layer 330 and the semiconductor layer 340 within the laminate pattern 350 are, for example, formed by the same photomask patterning. Hence, the shape of the laminate pattern 350 is, for example, an island. The gate insulating layer 360 is disposed on the transparent substrate 310 to cover the laminate pattern 350. The gate electrode 370 is disposed on the gate insulating layer 342 above the channel 360.

As being applied in a liquid crystal display, the light-shielding layer 320 of the thin film transistor 300 is disposed on the optical path of the backlight B. When the light shone on the thin film transistor 300, the energy of the light excites some ions in the light-shielding layer 320 and the excited ions are trapped in the defects or the grain boundary traps of the light-shielding layer 320 to achieve light-shielding and protect the thin film transistor 300 from being interfered by the backlight B.

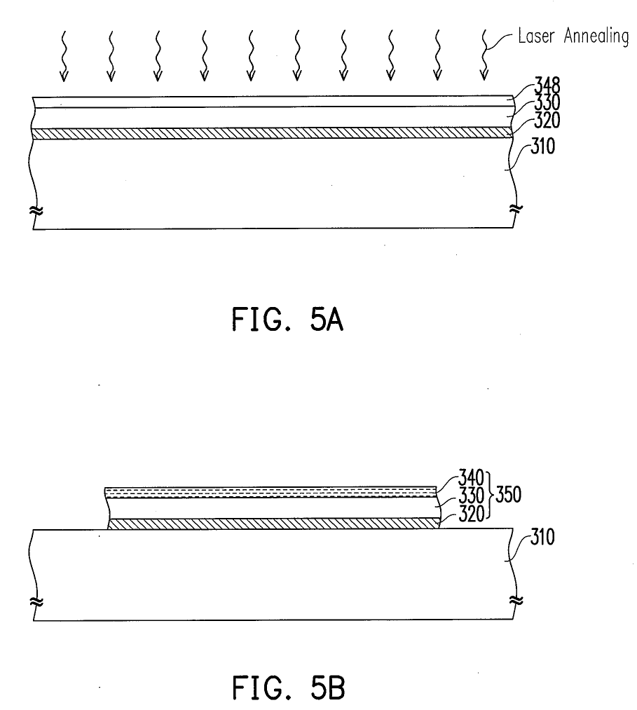

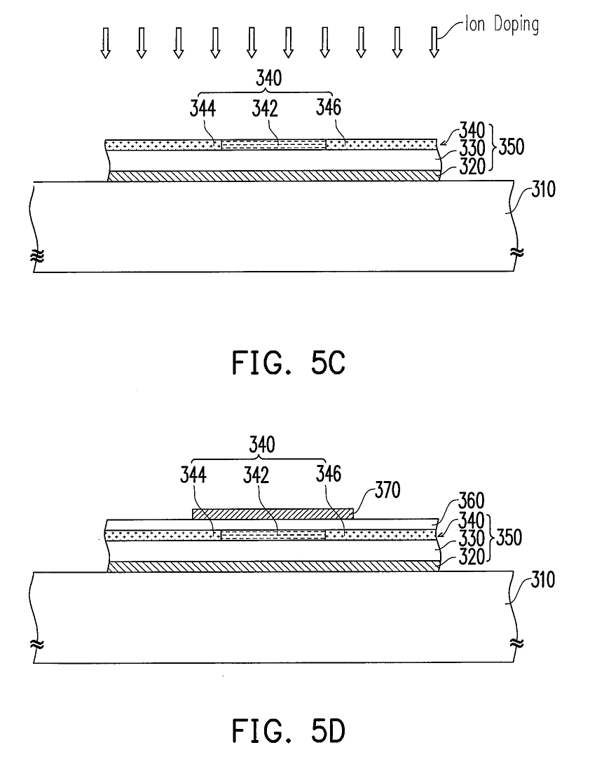

To further illustrate the features of the present invention, another process for fabricating the above-mentioned thin film transistor 300 is described below. FIG. 5A through FIG. 5D illustrate the steps for fabricating the thin film transistor shown in FIG. 4.

Please refer to FIG. 5A, a transparent substrate 310 is first provided. Next, a light-shielding layer 320 is formed over the transparent substrate 310. After a first buffer layer 330 is formed on the light-shielding layer 320, a semiconductor layer 340 (shown in FIG. 5B) is formed over the first buffer layer 330. In the present embodiment, the method used for fabricating the semiconductor layer 340 (shown in FIG. 5B) includes forming an amorphous silicon layer 348 on the first buffer layer 330, and followed by performing a laser annealing process to the amorphous silicon layer 348 to transform the amorphous silicon layer 348 into a polysilicon layer. Herein, the aforementioned laser annealing process is, for example, an excimer laser annealing (ELA) process, a sequential lateral solidification (SLS) process, or a thin beam direction X'rystallization process. Further, in the present embodiment, the material used for fabricating the light-shielding layer 320 includes amorphous silicon, polysilicon, diamond-like carbon, silicon germanium (SiGe), germanium, gallium arsenide (GaAs) or a combination thereof. In addition, the light-shielding layer 320 formed is at least 10 nm thick. More preferably, the thickness of the light-shielding layer 320 formed is between 50 nm and 300 nm, and even more preferably, between 50 nm and 100 nm. Moreover, the material used for fabricating the first buffer layer 330 is, for example, silicon oxide.

Thereafter, please refer to FIG. 5B. The light-shielding layer 320, the first buffer layer 330 and the semiconductor layer 340 are patterned to form a laminate pattern 350. As shown in FIG. 5B, the light-shielding layer 320, the first buffer layer 330 and the semiconductor layer 340 within the laminate pattern 350 are, for example, formed by the same photomask process. Hence, the shape of the laminate pattern 350 appears to be island-like. Further, the method for fabricating the light-shielding layer 320, the first buffer layer 330 and the semiconductor layer 340 includes, for example, performing a photolithographic process first, and followed by performing a wet etching process. In other embodiments, a dry etching process can also be adopted.

Next, as shown in FIG. 5C, a channel 342 and a source region 344/drain region 346 at two sides of the channel are formed within the semiconductor layer 340. Herein, the method used for forming the source region 344/drain region 346 is, for example, performing an ion doping process to a portion of the semiconductor layer and the dopant is, for example, p-type dopant or n-type dopant. Further, the method used for doping is, for example, an ion shower process or an ion implantation process.

Next, as shown in FIG. 5D, a gate insulating layer 360 is formed over the transparent substrate 310 to cover the laminate patter 350. Thereafter, a gate electrode 370 is formed on the gate insulating layer 360 above the channel 342. Herein, the material used for fabricating the gate insulating layer 360 is, for example, silicon oxide, silicon nitride or an organic material. The method used for fabricating the gate insulting layer 360 includes, for example, performing a chemical vapor deposition process, and followed by performing a patterning process. Further, the method used for fabricating the gate electrode 370 includes, for example, performing a sputtering process or an evaporation process, and followed by performing a patterning process. The above-mentioned patterning process includes, for example, performing a photolithographic process, and followed by performing a wet etching process or a dry etching process.

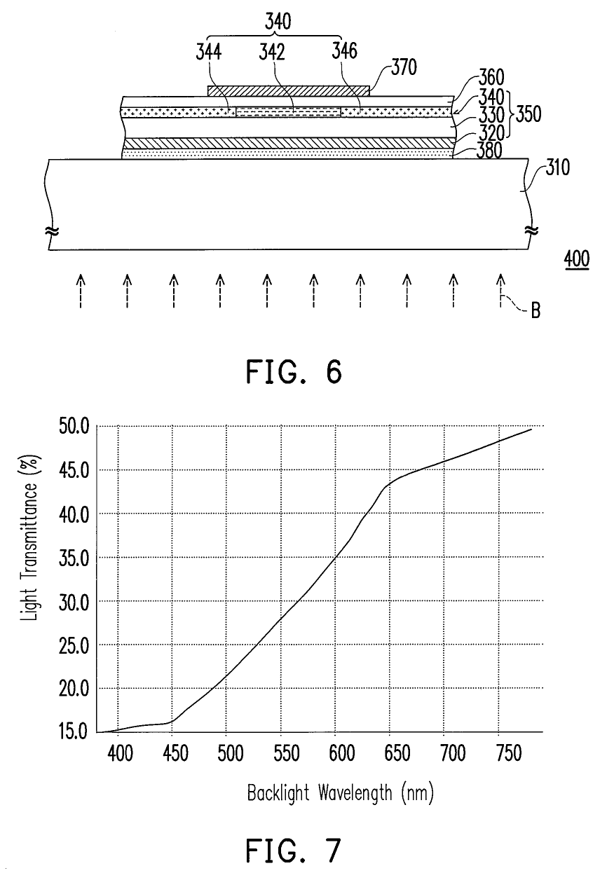

Besides the above-mentioned fabrication method, the thin film transistor 300 can also be fabricated according to another embodiment of the present invention. According to the embodiment, a second buffer layer 380 is formed on the transparent substrate 310 prior to the formation of the light-shielding layer 320. Hence, the second buffer layer 380 is formed between the light-shielding layer 320 and the transparent substrate 310, forming a thin film transistor 400 as shown in FIG. 6. The second buffer layer 380 can block the metal impurities of the transparent substrate to prevent the metal impurities from diffusing into the thin film transistor 400 during the succeeding high-temperature fabrication process which results in damages to the transistor devices. Further, the material used for fabricating the second buffer layer usually includes silicon nitride.

Please refer to FIG. 6, the backlight B for the thin film transistor 400 used in a liquid crystal display is disposed on the side of the substrate 310. To further determine the blocking effects of the light-shielding layer 320 for the backlight B, FIG. 7 illustrates the light transmittance of the light shone from the backlight B through the thin film transistor of FIG. 6 that reaches the semiconductor layer. As shown in FIG. 7, less than 50% of the lights having different wavelengths shone from the backlight B reaches the semiconductor layer 340. In a conventional device, without the presence of the light-shielding layer, the light transmittance reaches as high as 90%. Therefore, the light-shielding layer of the thin film transistor 400 can effectively reduce the interference level of the lights shone from the backlight B on the thin film transistor 400, reducing the amount of optical current leakage and improving the display quality of the liquid crystal display.

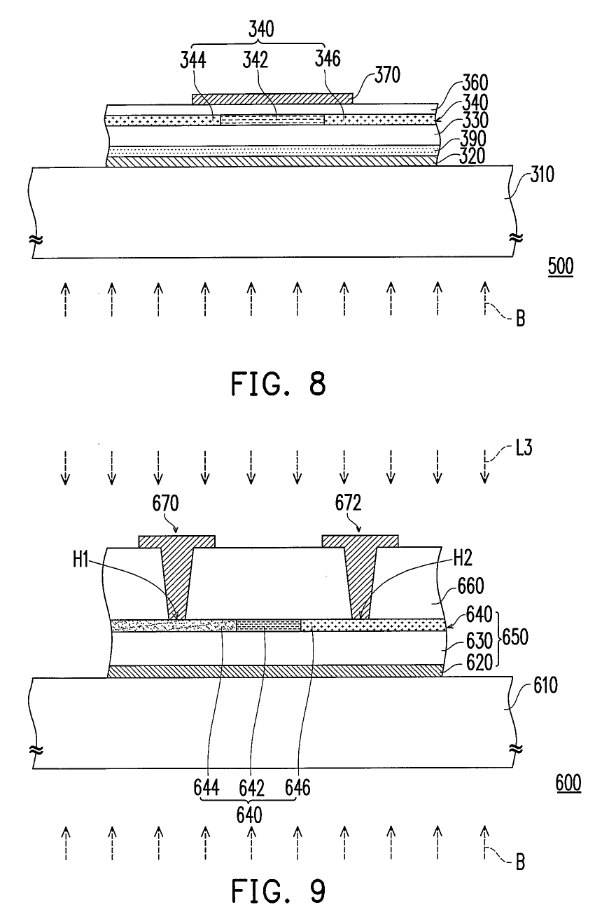

Further, as shown in FIG. 8, according to another embodiment of the present invention, during the fabrication process of the above-mentioned thin film transistor 300, a third buffer layer 390 is formed on the light-shielding layer 320 prior to the formation of the first buffer layer 330 to form a thin film transistor 500. Herein, the material used for fabricating the third buffer layer 390 is, for example, silicon nitride. Further, the material used for fabricating the light-shielding layer does not only include amorphous silicon, polysilicon, diamond-like carbon, silicon germanium (SiGe) alloy/compound, germanium, gallium arsenide (GaAs) or a combination thereof, it also includes molybdenum (Mo), aluminum (Al), chromium (Cr), titanium (Ti), or an alloy thereof. When the material used for fabricating the light-shielding layer is a metal such as molybdenum (Mo), aluminum (Al), chromium (Cr), or titanium (Ti), the metal material is usually opaque and directly reflects unnecessary lights to achieve light-shielding. When using a metal as the material for fabricating the light-shielding layer, precautions should be taken to prevent the metal ions of the metal material from diffusing into the thin film transistor 500. Hence, in the present embodiment, the third buffer layer 390 acts as a diffusion barrier layer which effectively blocks the metal ions in the light-shielding layer 320 from diffusing into the semiconductor layer 340 to prevent interferences and damages to the thin film transistor 500.

Therefore, when the semiconductor device of the present invention is used as a thin film transistor in a liquid crystal display, disposing a light-shielding layer in the thin film transistor to block unnecessary lights, compared to the conventional techniques, can effectively reduce the interference of unnecessary light such as the backlight B. In addition, the fabrication of the thin film transistor is compatible to the conventional fabrication process of the semiconductor device. In other words, no further fabrication process or manufacturing cost is required. Furthermore, light interference on the thin film transistor is effectively reduced, ensuring the photoelectric properties of the transistor and enhancing the display quality of the liquid crystal display.

FIG. 9 schematically illustrates a semiconductor device used in a photo-sensor according to one embodiment of the present invention. The semiconductor device is, for example, a PIN diode. Please refer to FIG. 9. In FIG. 9, a PIN diode 600 includes a transparent substrate 610, a light-shielding layer 620, a first buffer layer 630, a semiconductor layer 640, a protection layer 660, a first contact 670, and a second contact 672. Herein, the light-shielding layer 620 is disposed on the transparent substrate 610 and the material used for fabricating the light-shielding layer 620 is, for example, amorphous silicon, polysilicon, diamond-like carbon, silicon germanium (SiGe), germanium, gallium arsenide (GaAs) or any combination thereof. The light shielding layer is at least 10 nm thick. More preferably, the thickness of the light-shielding layer formed is between 50 nm and 300 nm, and even more preferably, between 50 nm and 100 nm. Further, the first buffer layer 630 is disposed on the light-shielding layer 620 and the material used for fabricating the first buffer layer 630 is, for example, silicon oxide. The semiconductor layer 640 is disposed on the first buffer layer 630 and the semiconductor layer 640 includes an intrinsic region 642, a first-type doped region 644, and a second-type doped region 646 at two sides of the intrinsic region 642. The laminate pattern 650 is formed by the light-shielding layer 620, the first buffer layer 630 and the semiconductor layer 640 that have substantially the same pattern. The light-shielding layer 620, the first buffer layer 630 and the semiconductor layer 640 in the laminate pattern 650 are, for example, formed by the same photomask process. Hence, the shape of the laminate pattern 650 appears to be island-like. Further, the protection layer 660 is formed on the transparent substrate 610 to cover the laminate pattern 650. Herein, the protection layer 660 includes a first contact window H1 and a second contact window H2, which are respectively used to expose a portion of the first-type doped region 644 and that of the second-type doped region 646. The first contact 670 and the second contact 672 are disposed on the protection layer 660. Herein, the first contact 670 is electrically connected to the first-type doped region 644 through the first contact window H1 and the second contact 672 is electrically connected to the second-type doped region 646 through the second contact window H2.

When the PIN diode 600 is used on a photo-sensor, the light-shielding layer 620 also plays the role of blocking unnecessary lights. More specifically, when an external light L3 is shone to the intrinsic region 642, electrons and holes are excited and photocurrent is generated. Next, the photocurrent is outputted through the first contact 670 and the second contact 672. The PIN diode 600 can be used as a detector for detecting the amount of the external light L3 for the liquid crystal display in order to adjust the brightness of the backlight module. In such application, the light-shielding layer 620 disposed on the optical path of the backlight B can effectively transform the light energy of the backlight B to ions and the ions are trapped in the defects or the grain boundary traps of the light-shielding layer 620 to achieve light-shielding. Such disposition of the light-shielding layer 620 can effectively reduce the interference caused by the backlight B when determining the amount of the external light L3. Thus, errors are prevented when the PIN diode 600 determines the amount of the external light L3, and the accuracy for adjusting the brightness of the backlight module is improved.

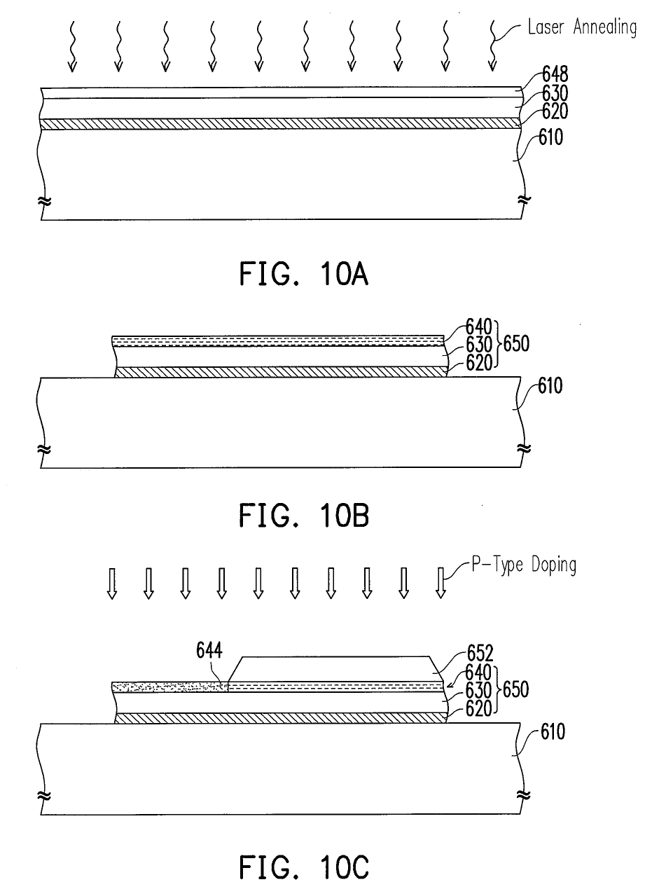

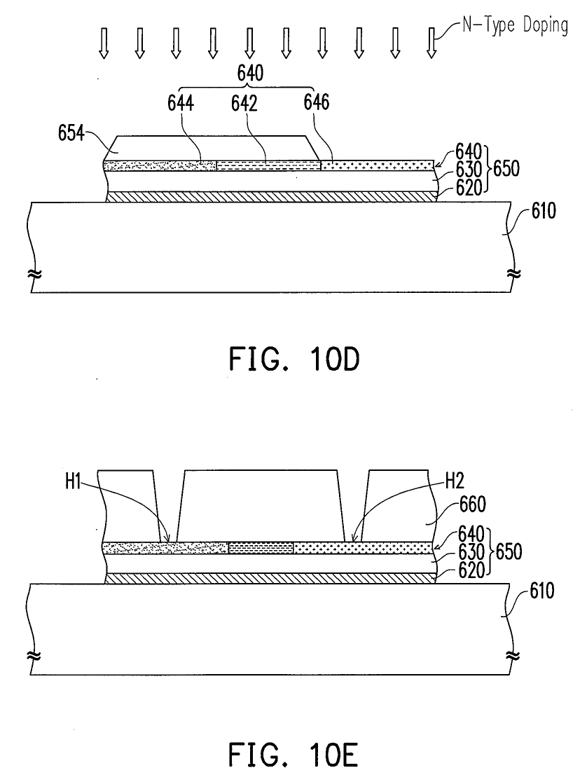

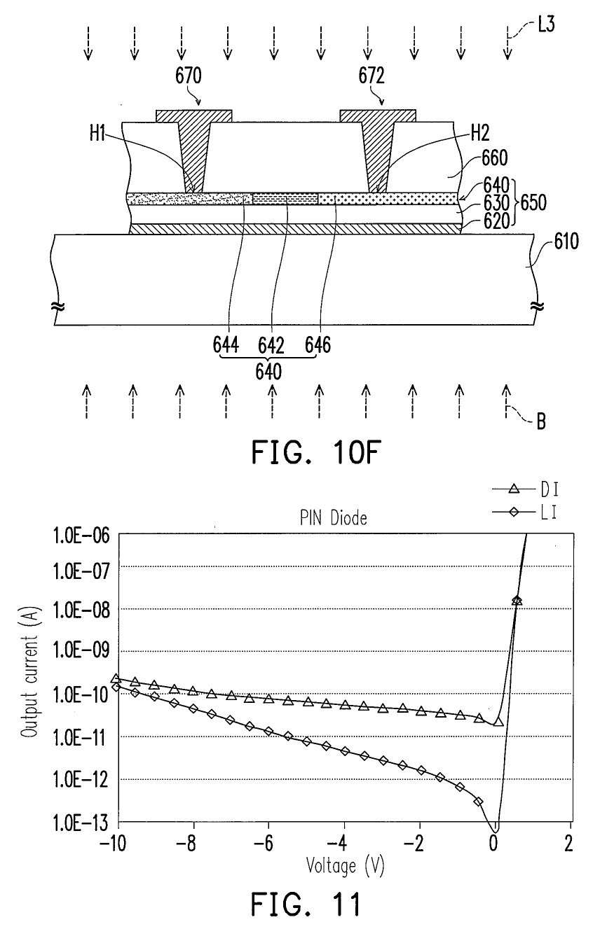

Nevertheless, there are many methods to fabricate the PIN diode 600. One method to fabricate the PIN diode 600 is described below. FIG. 10A through FIG. 10F schematically illustrate a fabricating method of a PIN diode used in a photo-sensor according to one embodiment of the present invention.

Please refer to FIG. 10A, a transparent substrate 610 is first provided. Next, a light-shielding layer 620 is formed over the transparent substrate 610. After a first buffer layer 630 is formed on the light-shielding layer 620, a semiconductor layer 640 is formed over the first buffer layer 630. Further, the principle of light-shielding, the material and the method used for fabricating the light shielding layer 620, and the material and the method used for fabricating the first buffer layer 630 are similar to that for the above-mentioned thin film transistor 300. Hence, a detailed description thereof is omitted. Additionally, the method used for fabricating the semiconductor layer 640 is similar to that for fabricating the above-mentioned thin film transistor 300, which is, for example, a laser annealing process.

Thereafter, as shown in FIG. 10B, the light-shielding layer 620, the first buffer layer 630, and the semiconductor layer 640 are patterned to acquire the same pattern substantially and form a laminate pattern 650. As shown in FIG. 10B, the light-shielding layer 620, the first buffer layer 630 and the semiconductor layer 640 in the laminate pattern 650 are, for example, formed by the same photomask process. Hence, the shape of the laminate pattern 650 appears to be island-like. The method used for patterning is similar to that for the above-mentioned thin film transistor 300. Hence, a detailed description thereof is omitted.

Afterward, as shown in FIG. 10C, a first photoresist layer 652 that exposes the first-type doped region 644 is formed on the semiconductor layer 640. Next, as shown in FIG. 10C, an ion doping process is performed by using the first photoresist layer 652 as a mask. As shown in FIG. 10C, the ion doping process is, for example, a P-type doping, which is used to form the first-type doped region 644. Thereafter, the first photoresist layer 652 is removed and the method used for removing the first photoresist layer 652 is, for example, a wet etching process.

Afterward, as shown in FIG. 10D, a second photoresist layer 654 that exposes the second-type doped region 646 is formed on the semiconductor layer 640. Next, as shown in FIG. 10D, an ion doping process is performed by using the second photoresist layer 654 as a mask. The ion implantation process is, for example, an N-type doping, which is used to form the second-type doped region 646. Thereafter, the second photoresist layer 654 is removed and the method used for removing the second photoresist layer 654 is, for example, a wet etching process. The above-mentioned method for doping is, for example, an ion shower process or an ion implantation process. Up to this step, an intrinsic region 642, and the first-type doped region 644 and the second-type doped region 646 at two sides of the intrinsic region 642 have already been formed within the semiconductor layer 640. In the present embodiment, the first-type doped region 644 that is doped with P-type dopants, the intrinsic region 642, and the second-type doped region 646 that are doped with N-type dopants form a PIN diode.

Thereafter, as shown in FIG. 10E, a protection layer 660 is formed over the transparent substrate 610 to cover the laminate pattern 650. Herein, the protection layer 660 includes a first contact window H1 and a second contact window H2, which are respectively used to expose a portion of the first-type doped region 644 and that of the second-type doped region 646. Herein, the material used for fabricating the protection layer 660 is, for example, silicon oxide, silicon nitride or an organic material and the method for fabricating the same includes, for example, performing a chemical vapor deposition, and followed by performing a patterning process.

Finally, as shown in FIG. 10F, a first contact 670 and a second contact 672 are disposed on the protection layer 660. Herein, the first contact 670 is electrically connected to the first-type doped region 644 through the first contact window H1 and the second contact 672 is electrically connected to the second-type doped region 646 through the second contact window H2.

Please refer to FIG. 10F. When the PIN diode 600 is used in a touch panel, the backlight B is disposed on the side of the substrate 610. To further determine the influence of the light-shielding layer 620 on the backlight B of the PIN diode 600, FIG. 11 schematically illustrates the influence of an external light on the output current of the PIN diode 600. In such application, the PIN diode 600 is used to act as a switch by detecting the presence and the absence of the external light L3. More specifically, when no object is blocking the external light L3, the output current of the PIN diode 600 is known as light current. On the other hand, when an object such as a finger is blocking the external light L3, the output current of the PIN diode 600 is known as dark current. It should be noted that the ratio of the light current (LI) to the dark current (DI) is used as an indicator for determining the sensitivity of the PIN diode 600. As shown in FIG. 11, since the light-shielding layer 620 is disposed in the PIN diode 600, the interference of the backlight B is alleviated. Comparing to the conventional device, the ratio of the light current (LI) to the dark current (DI) is significantly increased, further improving the sensitivity of the semiconductor device.

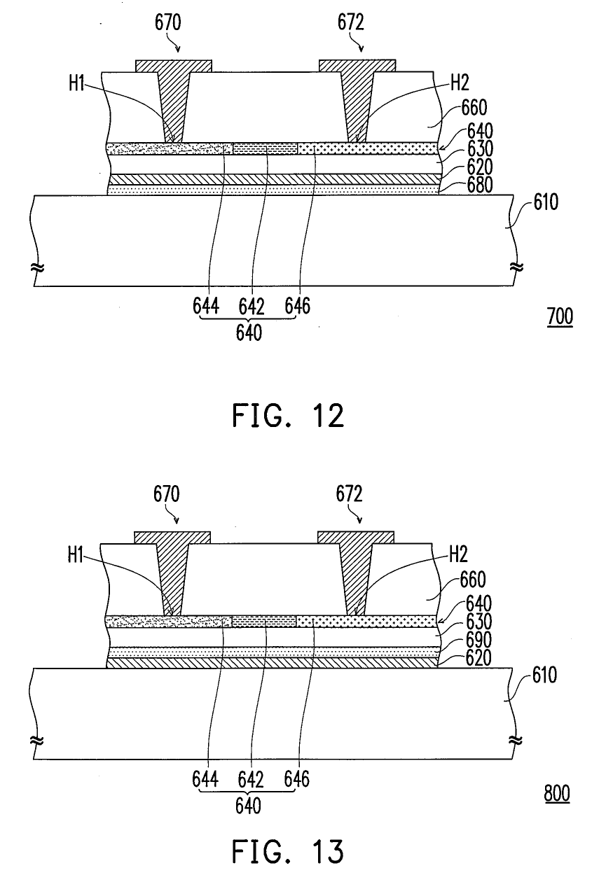

Besides the above-mentioned fabrication method, a second buffer layer 680 is formed prior to the formation of the light-shielding layer 620. Hence, the second buffer layer 680 is formed between the light-shielding layer 620 and the transparent substrate 610, forming a PIN diode 700 used in a touch panel according to another embodiment, as shown in FIG. 12. Herein, the second buffer layer 680 can be used as a diffusion barrier layer to block the metal impurities in the transparent substrate 610 and the material used for fabricating the same usually includes silicon nitride. Further, the material used for fabricating the light-shielding layer 620 is, for example, amorphous silicon, polysilicon, diamond-like carbon, silicon germanium (SiGe), germanium, gallium arsenide (GaAs) or a combination thereof. In addition, the principle of light-shielding for the light-shielding layer 620 is similar to that for the light-shielding layer 320 of the thin film transistor 300. Hence, a detailed description thereof is omitted.

Moreover, a PIN diode 800 used in a touch panel is fabricated according to another embodiment of the present invention, as shown in FIG. 13. The PIN diode 800 is formed by disposing a third buffer layer 690 between the first buffer layer 630 and the light-shielding layer 620 in the above-mentioned PIN diode 600. The method used for fabricating the PIN diode 800 is, for example, forming a third buffer layer 690 on the light-shielding layer 620 prior to the formation of the first buffer layer 630 during the fabrication process of the above-mentioned PIN diode 600. Herein, the material used for fabricating the light-shielding layer 620 can be amorphous silicon, polysilicon, diamond-like carbon, silicon germanium (SiGe), germanium, gallium arsenide (GaAs) or a combination thereof, and it can also be molybdenum (Mo), aluminum (Al), chromium (Cr), titanium (Ti), or an alloy thereof. In this structure, when the material used for fabricating the light-shielding layer 620 is a semiconductor material or a metal material, the principle of light-shielding is similar to that for the light-shielding layer 320 of the above-mentioned thin film transistor. Further, the third buffer layer 690 is also used similarly as the third buffer layer 390 of the above-mentioned thin film transistor. Hence, a detailed description thereof is omitted.

In view of the above, the semiconductor device of the present invention uses a light-shielding layer as a barrier layer to block unnecessary lights. Depending on the application of the semiconductor, the light-shielding layer can be either disposed on the optical path of the unnecessary external light or the optical path of the backlight B disposed in the bottom of the substrate. Hence, the present invention is not limited to the types of semiconductor devices. In other words, the concept of the present invention can be applied to photo-sensitive semiconductor devices. To maintain the efficiency of the device, a light-shielding layer is disposed on the optical path of unnecessary lights in the device to block the interference of unnecessary lights on the semiconductor device. Further, the fabrication of the light-shielding layer is compatible to the fabrication of the semiconductor device. The fabrication process does not require additional photomask fabrication. In addition, the production yield is improved and the manufacturing cost is reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for manufacturing a semiconductor device, comprising:
(a). providing a transparent substrate;
(b). forming a light-shielding layer over the transparent substrate;
(c). forming a first buffer layer on the light-shielding layer;
(d). forming a semiconductor layer on the first buffer layer;
(e). patterning the light-shielding layer, the first buffer layer, and the semiconductor layer to form a laminate pattern;
(f). forming a channel within the semiconductor layer and a source/drain region at two sides of the channel;
(g). forming a gate insulating layer over the transparent substrate to cover the laminate pattern; and
(h). forming a gate electrode on the gate insulating layer above the channel.

2. The method of claim 1, wherein step (d) comprises:
(i). forming an amorphous silicon layer on the first buffer layer; and
(j). performing a laser annealing process to transform the amorphous silicon layer into a polysilicon layer.

3. The method of claim 2, wherein the laser annealing process comprises an excimer laser annealing process, a sequential lateral solification process, or a thin beam direction X'rystallization process.

4. The method of claim 1, wherein step (e) comprises performing a wet etching process.

5. The method of claim 1, wherein forming the source/drain region in the semiconductor layer comprises performing an ion implantation process to a portion of the semiconductor layer.

6. The method of claim 1, further comprising forming a second buffer layer on the transparent substrate prior to the formation of the light-shielding layer.

7. The method of claim 1, further comprising forming a third buffer layer on the light-shielding layer prior to the formation of the first buffer layer.

8. A semiconductor device, comprising:
a transparent substrate;
a light-shielding layer disposed on the transparent substrate;
a first buffer layer disposed on the light-shielding layer;
a semiconductor layer disposed on the first buffer layer and having a channel and a source/drain region at two sides of the channel, wherein the light-shielding layer, the first buffer layer, and the semiconductor layer that have substantially the same pattern form a laminate pattern;
a gate insulating layer disposed over the transparent substrate to cover the laminate pattern; and
a gate electrode disposed on the gate insulating layer above the channel.

9. The device of claim 8, wherein the laminate pattern appears island-like.

10. The device of claim 8, wherein the material used for fabricating the light-shielding layer comprises amorphous silicon, polysilicon, diamond-like carbon, silicon germanium (SiGe), germanium, gallium arsenide (GaAs) molybdenum (Mo), aluminum (Al), chromium (Cr), titanium (Ti), or any combination thereof.

11. The device of claim 8, wherein the light-shielding layer is at least 10 nm thick.

12. The device of claim 11, wherein the thickness of the light-shielding layer is between 50 nm and 300 nm.

13. The device of claim 8, wherein the material used for fabricating the first buffer layer comprises silicon oxide.

14. The device of claim 8, further comprising a second buffer layer disposed between the light-shielding layer and the transparent substrate.

15. The device of claim 14, wherein the material used for fabricating the second buffer layer comprises silicon nitride.

16. The device of claim 8, further comprising a third buffer layer disposed between the first buffer layer and the light-shielding layer.

17. The device of claim 16, wherein the material used for fabricating the third buffer layer comprises silicon nitride.

18. A method for manufacturing a semiconductor device, comprising:
(a). providing a transparent substrate;
(b). forming a light-shielding layer over the transparent substrate;
(c). forming a first buffer layer on the light-shielding layer;
(d). forming a semiconductor layer on the first buffer layer;
(e). patterning the light-shielding layer, the first buffer layer, and the semiconductor layer to form a laminate pattern;
(f). forming an intrinsic region, and a first-type doped region and a second-type doped region at two sides of the intrinsic region within the semiconductor layer;
(g). forming a protection layer on the transparent substrate to cover the laminate pattern, wherein the protection layer comprises a first contact window and a second contact window respectively exposing a portion of the first-type doped region and that of the second-type doped region; and
(h). forming a first contact and a second contact on the protection layer, wherein the first contact is electrically connected to the first-type doped region through the first contact window and the second contact is electrically connected to the second-type doped region through the second contact window.

19. The method of claim 18, wherein step (d) comprises:
(i). forming an amorphous silicon layer on the first buffer layer; and
(j). performing a laser annealing process to transform the amorphous silicon layer into a polysilicon layer.

20. The method of claim 19, wherein the laser annealing process comprises an excimer laser annealing process, a sequential lateral solification process or a thin beam direction X'rystallization process.

21. The method of claim 18, wherein step (e) comprises performing a wet etching process.

22. The method of claim 18, wherein forming the first-type doped region and the second-type doped region in the semiconductor layer comprises respectively performing a P-type doping and an N-type doping to different portions of the semiconductor layer.

23. The method of claim 18, further comprising forming a second buffer layer on the transparent substrate prior to the formation of the light-shielding layer.

24. The method of claim 18, further comprising forming a third buffer layer on the light-shielding layer prior to the formation of the first buffer layer.

25. A semiconductor device, comprising:
a transparent substrate;
a light-shielding layer disposed on the transparent substrate;
a first buffer layer disposed on the light-shielding layer;
a semiconductor layer having an intrinsic region, and a first-type doped region and a second-type doped region at two sides of the intrinsic region disposed on the first buffer layer, wherein the light-shielding layer, the first buffer layer, and the semiconductor that have substantially the same pattern form a laminate pattern;
a protection layer disposed on the transparent electrode to cover the laminate pattern, wherein the protection layer comprises a first contact window and a second contact window respectively exposing a portion of the first-type doped region and that of the second-type doped region; and
a first contact and a second contact disposed on the protection layer, wherein the first contact is electrically connected to the first-type doped region through the first contact window and the second contact is electrically connected to the second-type doped region through the second contact window.

26. The device of claim 25, wherein the laminate pattern appears island-like.

27. The device of claim 25, wherein the material used for fabricating the light-shielding layer comprises amorphous silicon, polysilicon, diamond-like carbon, silicon germanium (SiGe), germanium, gallium arsenide (GaAs) molybdenum (Mo), aluminum (Al), chromium (Cr), titanium (Ti), or a combination thereof.

28. The device of claim 25, wherein the light-shielding layer is at least 10 nm thick.

29. The device of claim 28, wherein the thickness of the light-shielding layer is between 50 nm and 300 nm.

30. The device of claim 25, wherein the material used for fabricating the first buffer layer comprises silicon oxide.

31. The device of claim 25, further comprising a second buffer layer disposed between the light-shielding layer and the transparent substrate.

32. The device of claim 31, wherein the material used for fabricating the second buffer layer comprises silicon nitride.

33. The device of claim 25, further comprising a third buffer layer disposed between the first buffer layer and the light-shielding layer.

34. The device of claim 33, wherein the material used for fabricating the third buffer layer comprises silicon nitride.
